(19) United States
(12) Patent Application Publication
(10) Pub. No.: US 2015/0179234 A1
(43) Pub. Date: Jun. 25, 2015

(54) SEMICONDUCTOR SYSTEM AND POWER SOURCE CHIP

(71) Applicant: KABUSHIKI KAISHA TOSHIBA, Tokyo (JP)

(72) Inventors: Masayasu KAWASE, Yokohama (JP); Toyokazu EGUCHI, Inagi (JP)

(73) Assignee: KABUSHIKI KAISHA TOSHIBA, Tokyo (JP)

(21) Appl. No.: 14/276,765

(22) Filed: May 13, 2014

(30) Foreign Application Priority Data
Dec. 25, 2013 (JP) 2013-266654

(51) Int. Cl. G11C 5/14; G05F 5/00; G11C 14/00

(52) U.S. Cl. CPC G11C 5/148; G11C 14/0009; G05F 5/00

(57) ABSTRACT

A semiconductor system includes a semiconductor package having first and second semiconductor chips and a controller configured to control the first and second semiconductor chips, and a power source chip that is connected to a control line of the semiconductor package, and is configured to supply to the first and second semiconductor chips and the controller, power having different voltage or current levels that correspond to a voltage level of the control line.

### CROSS-REFERENCE TO RELATED APPLICATION

This application is based upon and claims the benefit of priority from Japanese Patent Application No. 2013-266654, filed Dec. 25, 2013, the entire contents of which are incorporated herein by reference.

### FIELD

Embodiments described herein relate generally to a semiconductor system and a power source chip of the semiconductor system.

### BACKGROUND

Generally, a semiconductor system includes one or more semiconductor chips and a power source chip which supplies power to the one or more semiconductor chips. It is desirable that a single power source chip is compatible with plural semiconductor chips that have different designs.

### DESCRIPTION OF THE DRAWINGS

FIG. 1 is a block diagram exemplifying a semiconductor system according to a first embodiment.

FIG. 2 is a block diagram exemplifying an internal configuration of a power source chip according to the first embodiment.

FIG. 3 is a block diagram of a first example of the semiconductor system according to the first embodiment.

FIG. 4 is a block diagram of a second example of the semiconductor system according to the first embodiment.

FIG. 5 is a block diagram exemplifying a semiconductor system according to a second embodiment.

FIG. 6 is a block diagram of a first example of a semiconductor system according to a third embodiment.

FIG. 7 is a cross-sectional view of a semiconductor system according to the third embodiment.

FIG. 8 is a block diagram exemplifying a second measure of the semiconductor system according to the third embodiment.

FIG. 9 is a block diagram exemplifying a semiconductor system according to a fourth embodiment.

### DETAILED DESCRIPTION

In general, according to one embodiment, a semiconductor system includes a semiconductor package having first and second semiconductor chips and a controller configured to control the first and second semiconductor chips, and a power source chip that is connected to a control line of the semiconductor package, and is configured to supply to the first and second semiconductor chips and the controller, power having different voltage or current levels that correspond to a voltage level of the control line.

Hereinafter, embodiments are explained by reference to drawings.

In this disclosure, with respect to some elements, a plurality of expressions is used for expressing each constitutional element. However, these expressions are merely examples, and it is not denied that each of the above-mentioned constitutional elements is expressed using other expressions. Further, elements which are not expressed by a plurality of expressions may be also expressed by different expressions.

### First Embodiment

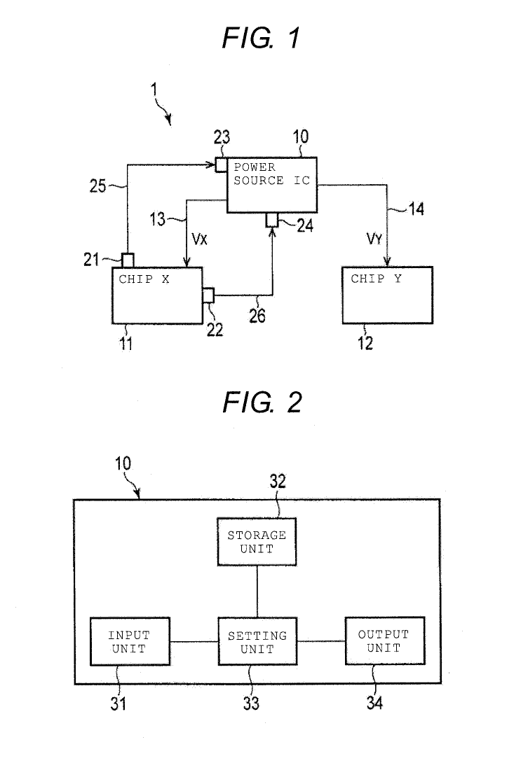

FIG. 1 shows a semiconductor system 1 according to a first embodiment. The semiconductor system 1 may be an example of “an electronic circuit” or “a system”. The semiconductor system 1 includes: a power source chip 10, a first semiconductor chip 11 (first chip), and a second semiconductor chip 12 (second chip).

The power source chip 10 is one example of “semiconductor component,” “semiconductor device,” and “package,” and supplies power to the plurality of semiconductor chips 11, 12. To explain the configuration of the power source chip 10 in detail, a first power source line 13 is provided between the power source chip 10 and the first semiconductor chip 11. The power source chip 10 supplies power to the first semiconductor chip 11 through the first power source line 13. In the same manner, a second power source line 14 is provided between the power source chip 10 and the second semiconductor chip 12. The power source chip 10 supplies power to the second semiconductor chip 12 through the second power source line 14.

As shown in FIG. 1, the first semiconductor chip 11 includes a first instruction terminal 21 (first terminal, first set terminal, first output terminal), and a second instruction terminal 22 (second terminal, second set terminal, second output terminal). The power source chip 10 includes a first input terminal 23 (first terminal) and a second input terminal 24 (second terminal).

A first input line 25 is provided between the first instruction terminal 21 of the first semiconductor chip 11 and the first input terminal 23 of the power source chip 10. A first input (first instruction) can be input from the first instruction terminal 21 to the power source chip 10 through the first input line 25.

In the same manner, a second input line 26 is provided between the second instruction terminal 22 of the first semiconductor chip 11 and the second input terminal 24 of the power source chip 10. A second input (second instruction) can be input from the second instruction terminal 22 to the power source chip 10 from the second input line 26.

In this embodiment, the input of the first input and the second input is performed in a condition in which a voltage applied to the first input terminal 23 and the second input terminal 24 of the power source chip 10 is fixed at a level lower than a desired voltage (predetermined voltage) or a level higher than the desired voltage (predetermined voltage). For example, the input of the first input and the second input are performed in a condition in which the voltage applied to the first input terminal 23 and the second input terminal 24 are fixed at a Low level (0) or at a High level (1). Here, a voltage at a Low level (0) is one example of the voltage lower than the desired voltage (predetermined voltage) and a voltage at a High level (1) is one example of the voltage higher than the desired voltage (predetermined voltage).

To explain the configuration of the semiconductor chip 1 in more detail, the first instruction terminal 21 of the first semiconductor chip 11 is electrically connected to a ground or to a power source line (power source layer) of the first semiconductor chip 11 or a printed circuit board, for example. When the first instruction terminal 21 is electrically connected to the ground, a voltage at a Low level (0) is applied to the first input terminal 23 of the power source chip 10 as the first input. On the other hand, when the first instruction terminal 21 is electrically connected to the power source line, a voltage at a High level (1) is applied to the first input terminal 23 of the power source chip 10 as the first input.

In the same manner, the second instruction terminal 22 of the first semiconductor chip 11 is electrically connected to the ground or to the power source line (power source layer) of the first semiconductor chip 11 or the printed circuit board, for example. When the second instruction terminal 22 is electrically connected to the ground, a voltage at a Low level (0) is applied to the second input terminal 24 of the power source chip 10 as the second input. On the other hand, when the second instruction terminal 22 is electrically connected to the power source line, a voltage at a High level (1) is applied to the second input terminal 24 of the power source chip 10 as the second input.

With such a configuration, plural kinds of inputs can be input to the power source chip 10 in accordance with the combinations of a voltage applied to the first input terminal 23 and a voltage applied to the second input terminal. In this embodiment, four kinds of inputs (0, 0), (0, 1), (1, 0), and (1, 1) can be input. By performing any one of four kinds of inputs, the power source chip 10 sets a combination of output powers which the first semiconductor chip 11 and the second semiconductor chip 12 require.

The number of input lines provided between the first semiconductor chip 11 and the power source chip 10 may be one. In this case, by electrically connecting the instruction terminal of the first semiconductor chip 11 to the ground or to the power source line, the first semiconductor chip 11 may perform two kinds of inputs, that is, input of a voltage at a Low level (0) and input of a voltage at a High level (1) to the power source chip 10. Alternatively, an input transmitted from the instruction terminal of the first semiconductor chip 11 may be a pulse signal or other appropriate signals. In this case, even when the number of input lines is one, plural kinds of inputs may be provided.

FIG. 2 shows an internal configuration of the power source chip 10. The power source chip 10 includes an input unit 31, a storage unit 32, a setting unit 33 (determination unit, control unit), and an output unit 34. The input unit 31 includes the above-mentioned first input terminal 23 and second input terminal 24, and receives an external input. In this disclosure, the “external input” means an input from the outside of the power source chip 10, and includes an input from other units (the first semiconductor chip 11, for example) which constitute the semiconductor system 1. In this embodiment, the input unit 31 receives four kinds of inputs (0, 0), (0, 1), (1, 0), and (1, 1) from the first semiconductor chip 11.

The storage unit 32 stores a plurality of combinations of levels of power to be supplied to the plurality of semiconductor chips 11, 12 (that is, a plurality of combinations of outputting) with respect to levels of input to the power source chip 10. In this embodiment, the storage unit 32 stores four patterns of levels of power to be supplied the first and second semiconductor chips 11, 12, each pattern corresponding to a combination of the levels of the inputs.

The storage unit 32 stores the contents shown in Table 1, for example. In Table 1, “Input” indicates levels of input signals input to the power source chip 10 from the first semiconductor chip 11. (00), (01), (10), (11) in Table 1 represent four kinds of inputs (0, 0), (0, 1), (1, 0), (1, 1) in an abbreviated manner.

TABLE 1

| | | Voltage/V | |
|---|---|---|---|
| | | chipX [V_{X}] | chipY [V_{Y}] |
| Input | 00 | 1 | 1 |
| | 01 | 1 | 2 |
| | 10 | 2 | 1 |
| | 11 | 2 | 2 |

In Table 1, “Voltage” indicates the combination of a voltage level Vx applied to the first semiconductor chip 11 from the power source chip 10 and a voltage level Vy applied to the second semiconductor chip 12 from the power source chip 10. As shown in Table 1, the correspondence between four patterns of inputs to the power source chip 10 from the first semiconductor chip 11 and a combination of levels of voltage to be applied to the first and second semiconductor chips 11, 12 with respect to each pattern is stored in the storage unit 32 in advance.

The setting unit 33 sets one combination of levels of power in accordance with the inputs which the input unit 31 receives. In this embodiment, the setting unit 33 sets one combination of levels of voltage to be applied to the first and second semiconductor chips 11, 12 corresponding to one of four patterns of the inputs (0, 0), (0, 1), (1, 0), and (1, 1).

In this embodiment, as one example of combinations of levels of power to be supplied to the first and second semiconductor chips 11, 12 (combinations of outputs), the combinations of levels of voltage to be applied to the first and second semiconductor chips 11, 12 are stored. However, the combinations of levels of power to be supplied to the first and second semiconductor chips 11, 12 are not limited to the combinations of levels of voltage. For example, the combinations of levels of power to be supplied to the first and second semiconductor chips 11, 12 may be suitably set to one or a plurality of combinations of levels of voltage, current, or frequency.

In this case, for example, the power source chip 10 may change levels of powers to be supplied to the first and second semiconductor chips 11, 12 by switching a level of current output by switching a setting of a current limiter with respect to the first and second semiconductor chips 11, 12. Further, the power source chip 10 may change a level of power to be supplied to the first and second semiconductor chips 11, 12 by switching a switching frequency of the power source chip 10.

The output unit 34 supplies power to the first and second semiconductor chips 11, 12, the levels of which are based on the combination of voltage levels set by the setting unit 33. Accordingly, the power source chip 10 supplies power to at least one of the plurality of semiconductor chips 11, 12 in a variable manner. That is, the power source chip 10 according to this embodiment may output the different level combinations of powers by simultaneously switching outputs of a plurality of channels in response to inputs from the outside.

Next, operation of the semiconductor system 1 according to this embodiment is explained.

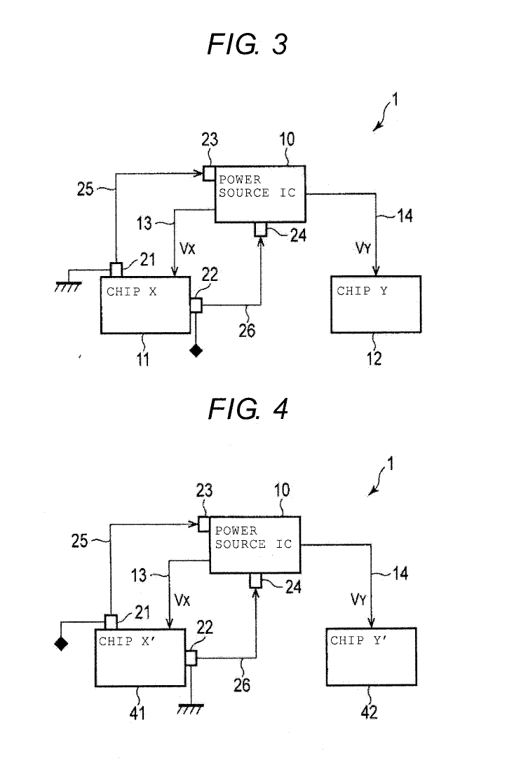

FIG. 3 shows a first example of the semiconductor system 1. In the first example, the first instruction terminal 21 of the first semiconductor chip 11 is electrically connected to the ground so that a voltage level of the first instruction terminal 21 is fixed to a Low level (0). On the other hand, the second instruction terminal 22 is electrically connected to the power source line so that a voltage level of the second instruction terminal 22 is fixed to a High level (1). Accordingly, an input (0, 1) is input to the power source chip 10 from the first instruction terminal 21.

The power source chip 10 receives the input from the instruction terminal 21, sets the level combination of powers corresponding to the input (0, 1) out of four patterns of stored combinations, and outputs a voltage of 1[V] to the first semiconductor chip 11 and a voltage of 2[V] to the second semiconductor chip 12 based on the setting.

There may be a case where a part of the semiconductor system 1 is modified corresponding to a required operating speed or a required manufacturing cost. FIG. 4 shows a second example, which is obtained by modifying a part of the first example of the semiconductor system 1.

In the semiconductor system 1 of the second example, the power source chip 10 is used in the same manner as in the first example, and the first and second semiconductor chips 11, 12 are replaced with third and fourth semiconductor chips 41, 42 which differ from the first and second semiconductor chips 11, 12 with respect to specified level of power used (specified voltage level used, for example).

As shown in FIG. 4, in the second example, a first instruction terminal 21 of the third semiconductor chip 41 is electrically connected to a power source line so that a voltage level of the first instruction terminal 21 is fixed to a High level (1). A second instruction terminal 22 of the third semiconductor chip 41 is electrically connected to a ground so that a voltage of the second instruction terminal 22 is fixed to a Low level (0). Accordingly, inputs (1, 0) are input to the power source chip 10 from the third semiconductor chip 41.

The power source chip 10 receives inputs from the third semiconductor chip 41, selects the level combination of powers corresponding to the input (1, 0) out of four patterns of stored combinations of powers, and supplies a voltage of 2[V] to the third semiconductor chip 41 and a voltage of 1 [V] to the fourth semiconductor chip 42. In this embodiment, levels of current supplied to the third and fourth semiconductor chips 41, 42 are substantially equal to levels of current supplied to the first and second semiconductor chips 11, 12. Accordingly, it is possible to provide the semiconductor system 1 having a different measure suitable for a desired operating speed or a desired manufacturing cost without replacing the power source chip 10.

According to the above-mentioned configuration, it is possible to provide the power source chip 10 with a higher level of versatility and the semiconductor system 1 that includes such a power source chip 10. That is, when a power source chip that cannot set a plurality of combinations of powers is used, it is necessary to use a unique power source chip corresponding to the circuit constitution. In such a case, when one or more chips included in the circuit are changed, it is necessary to replace the power source chip with a new power source chip suitable for the new circuit. Such replacement of the power source chip increases a manufacturing cost of the semiconductor system 1.

On the other hand, the power source chip 10 of this embodiment includes: the storage unit 32 that stores a plurality of level combinations of power to be supplied to the plurality of semiconductor chips 11, 12; the input unit 31 that receives external inputting; the setting unit 33 that sets one level combination of power out of the plurality of level combinations of power in accordance with inputs which the input unit 31 receives; and the output unit 34 that outputs power of the selected level combination.

Due to such a configuration, the plurality of level combinations of power to be supplied to the plurality of semiconductor chips 11, 12 may be stored in the power source chip 10 in advance, and powers corresponding to the semiconductor chips 11, 12 or the semiconductor chips 41, 42 can be output. Accordingly, powers having level suitable for the plural kinds of circuit configuration may be supplied.

That is, even when one or the plurality of semiconductor chips included in the circuit are changed, the semiconductor system 1 may be used without changing the power source chip 10. Due to such a configuration, it is possible to provide the power source chip 10 with a higher level of versatility. Accordingly, a manufacturing cost of the semiconductor system 1 may be lowered.

Further, according to the above-mentioned configuration, the level combination of power to be supplied to the plurality of semiconductor chips 11, 12 may be collectively set based on an external input, and hence, it would be unnecessary to individually adjust a level of power for the semiconductor chips 11, 12. Accordingly, it is possible to avoid a situation where excessively large power (large voltage) is supplied to one or more of semiconductor chips 11, 12 cause by mistakenly adjusting a level of power for the respective semiconductor chips 11, 12.

In this embodiment, the input unit 31 of the power source chip 10 receives the inputs from one of the plurality of semiconductor chips 11, 12. That is, the level combination of powers to be supplied to the plurality of semiconductor chips 11, 12 is collectively set based on inputs from one semiconductor chip, and hence, the setting of the semiconductor system 1 may be changed more easily.

For a comparison purpose, a case is considered where the setting of levels of power to be supplied to the plurality of semiconductor chips 11, 12 is controlled by the first semiconductor chip 11. In this case, to perform the above-mentioned setting, it is necessary that the first semiconductor chip 11 is operated. Accordingly, a time and power for operating the first semiconductor chip 11 are necessary to perform the above-mentioned input.

To the contrary, in this embodiment, the input unit 31 of the power source chip 10 includes the input terminals 23, 24. The above-mentioned input is performed by fixing voltages applied to the input terminals 23, 24 at a level lower than a predetermined voltage or at a level higher than the predetermined voltage. Due to such a configuration, even when the first semiconductor chip 11 is not operated, proper input may be made to the power source chip 10. Accordingly, a rise time of the semiconductor system 1 may be shortened and standby power may be reduced.

In this embodiment, the input unit 31 of the power source chip 10 includes the first input terminal 23 and the second input terminal 24. The above-mentioned input is performed based on the combination of a voltage applied to the first input terminal 23 and a voltage applied to the second input terminal 24. Due to such a configuration, three or more kinds of inputs may be performed without using a control unit. Accordingly, the versatility of the power source chip 10 may be further enhanced.

### Second Embodiment

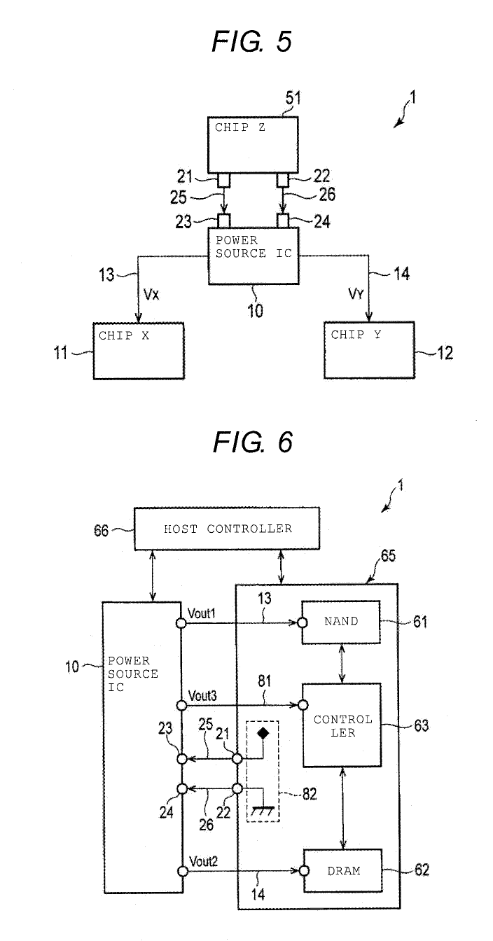

Next, a semiconductor system 1 according to a second embodiment is explained by reference to FIG. 5. An element that is identical to or similar to the corresponding element of the first embodiment is shown with a same numeral, and explanation of these elements is omitted. Elements other than the ones explained below are equal to the corresponding elements of the first embodiment.

FIG. 5 is a schematic view of the semiconductor system 1 according to the second embodiment. The semiconductor system 1 according to this embodiment includes: a power source chip 10; a first semiconductor chip 11; a second semiconductor chip 12; and a third semiconductor chip 51.

The third semiconductor chip 51 includes a first instruction terminal 21 and a second instruction terminal 22. A first input can be input from the instruction terminal 21 to the power source chip 10 through a first signal line 25. In the same manner, a second input can be input from the instruction terminal 22 to the power source chip 10 through a second signal line 26.

In this embodiment, in the same manner as the first embodiment, input of the first input and the second input are performed by fixing a voltage applied to a first input terminal 23 of the power source chip 10 and a voltage applied to a second input terminal 24 of the power source chip 10 at a level lower than a desired voltage (predetermined voltage) or a level higher than the desired voltage (predetermined voltage).

Due to such a configuration, in the same manner as in the first embodiment, it is possible to provide the power source chip 10 with a higher level of versatility, and the semiconductor system 1 which includes such a power source chip 10.

In this embodiment, an input unit 31 of the power source chip 10 receives input which sets levels of power to be supplied to the plurality of semiconductor chips 11, 12 from an external unit (additional part, for example) that is different from the semiconductor chips 11, 12. Also due to such a configuration, the semiconductor system 1 may collectively set the combination of powers to be supplied to the plurality of semiconductor chips 11, 12 based on the above-mentioned input and hence, a setting of the semiconductor system 1 may be changed more easily.

Power may be or may not be supplied to the third semiconductor chip 51 from the power source chip 10. A resistance of the third semiconductor chip 51 may be connected to a ground or to a power source line with resistance of 0Ω, for example. Power may be supplied to the third semiconductor chip 51 from a part other than the power source chip 10.

### Third Embodiment

Next, a semiconductor system 1 according to a third embodiment is explained by reference to FIG. 6 to FIG. 8. An element that is identical to or similar to the corresponding element of the first and second embodiments are shown with a same numeral, and explanation of these elements is omitted. Elements other than elements explained below are equal to the corresponding elements of the first embodiment.

FIG. 6 shows a semiconductor system 1 according to the third embodiment. The semiconductor system 1 includes: a power source chip 10; a NAND memory 61; a DRAM 62; and a controller 63. The NAND memory 61 is a so-called NAND-type flash memory, and is one example of “a NAND memory chip, “a nonvolatile memory”, “a semiconductor memory”, “a first semiconductor chip” or “a first chip”. Although only one NAND memory 61 is shown in FIG. 6, the semiconductor system 1 may include a plurality of NAND memories 61.

The Dynamic Random Access Memory (DRAM) 62 is one example of “a DRAM chip”, “a volatile memory”, “a second semiconductor chip” or “a second chip”. The controller 63 is one example of “controller chip”, “third semiconductor chip”, and “third chip”. The controller 63 is electrically connected to the NAND memory 61 and the DRAM 62, and controls the NAND memory 61 and the DRAM 62.

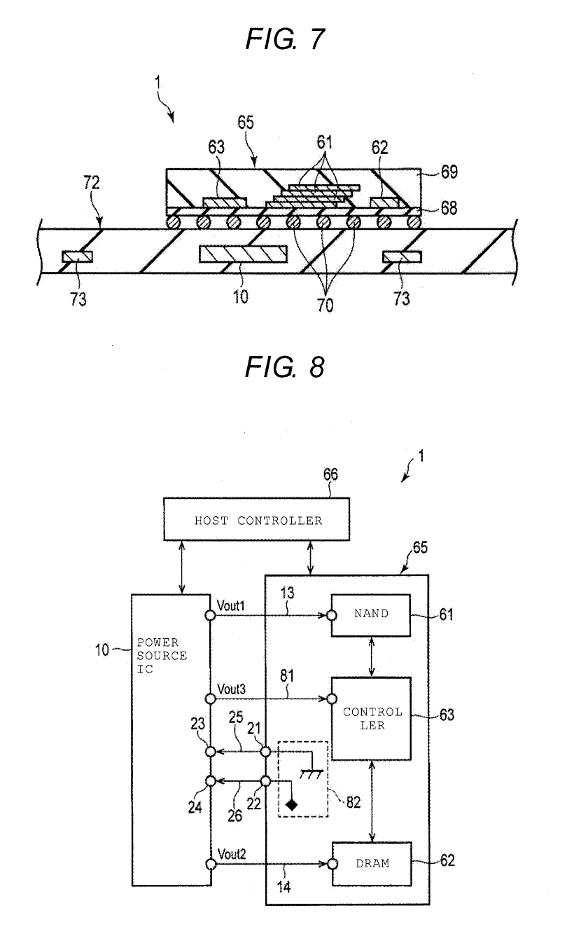

As shown in FIG. 7, the NAND memory 61, the DRAM 62, and the controller 63 are integrally formed as one semiconductor package 65. The semiconductor package 65 is a so-called BGA-SSD (Ball Grid Array—Solid State Drive), and is a package of a BGA type.

To explain the configuration of the semiconductor system 1 according to the third embodiment in more detail, the semiconductor package 65 includes a printed circuit board 68 (package printed circuit board). The NAND memory 61, the DRAM 62, and the controller 63 are electrically connected to the printed circuit board 68, and are integrally covered with a sealing member 69. A plurality of solder balls 70 is disposed on the printed circuit board 68 as connection terminals. The controller 63 according to this embodiment performs a comprehensive control of the whole semiconductor package 65.

As shown in FIG. 7, the semiconductor system 1 includes a printed circuit board 72 on which the semiconductor package 65 is mounted. The semiconductor package 65 is mounted on a surface of the printed circuit board 72. On the other hand, a plurality of parts 73 including a power source chip 10 are built in the printed circuit board 72. Alternatively, the power source chip 10 and the parts 73 may be mounted on the surface of the printed circuit board 72. As shown in FIG. 6, the semiconductor system 1 includes a host controller 66 which controls the semiconductor package 65 and the power source chip 10, for example.

As shown in FIG. 6, the power source chip 10 supplies power to the NAND memory 61, the DRAM 62, and the controller 63. To explain the configuration of the semiconductor system 1 in detail, a first power source line 13 is provided between the power source chip 10 and the NAND memory 61. The power source chip 10 supplies power to the NAND memory 61 through the first power source line 13.

In the same manner, a second power source line 14 is provided between the power source chip 10 and the DRAM 62. The power source chip 10 supplies power to the DRAM 62 through the second power source line 14. A third power source line 81 is provided between the power source chip 10 and the controller 63. The power source chip 10 supplies power to the controller 63 through the third power source line 81.

As shown in FIG. 6, the semiconductor package 65 includes a reference unit 82 (input reference unit). The reference unit 82 is electrically connected to a first instruction terminal 21 and a second instruction terminal 22. The reference unit 82 includes contacts connected to a ground and a power source line of the semiconductor package 65 or the printed circuit board 72, for example. Based on the configuration of the reference unit 82, the semiconductor package 65 may set respective levels of voltage applied to the first instruction terminal 21 and the second instruction terminal 22, for example.

A first input line 25 is provided between the first instruction terminal 21 of the semiconductor package 65 and a first input terminal 23 of the power source chip 10. A first input can be input from the first instruction terminal 21 of the semiconductor package 65 to the power source chip 10 through the first input line 25.

In the same manner, a second input line 26 is provided between the second instruction terminal 22 of the semiconductor package 65 and a second input terminal 24 of the power source chip 10. A second signal can be input from the second instruction terminal 22 of the semiconductor package 65 to the power source chip 10 through the second signal line 26.

In this embodiment, in the same manner as the first embodiment, for example, the input of the first input and the second input is performed by fixing respective voltages applied to the first input terminal 23 and the second input terminal 24 of the power source chip 10 at a level lower than a desired voltage (predetermined voltage) or a level higher than the desired voltage (predetermined voltage), for example. That is, Four kinds of inputs (0, 0), (0, 1), (1, 0), and (1, 1) can be input to the power source chip 10.

In this embodiment, a storage unit 32 of the power source chip 10 stores a plurality of level combinations of power to be supplied to the NAND memory 61, the DRAM 62, and the controller 63 with respect to each pattern of the combination of the inputs to the power source chip 10.

In this embodiment, as one example of the plurality of level combinations of power to be supplied to the NAND memory 61, the DRAM 62, and the controller 63, the storage unit 32 of the power source chip 10 stores a plurality of combinations of levels of voltage to be applied to the NAND memory 61, the DRAM 62, and the controller 63.

The storage unit 32 stores the contents shown in Table 2, for example. In Table 2, “Input” indicates an input to the power source chip 10 from the semiconductor package 65, and (00), (01), (10), and (11) in Table 2 represent four kinds of inputs (0, 0), (0, 1), (1, 0), (1, 1) in an abbreviated manner.

TABLE 2

| | | Voltage/V | | | | | |
|---|---|---|---|---|---|---|---|
| | | Vₒᵤₜ₁ | Vₒᵤₜ₂ | Vₒᵤₜ₃ | Vₒᵤₜ₄ | Vₒᵤₜ₅ | Vₒᵤₜ₆ |
| Input | 00 | 3.3 | 1.2 | 1.0 | . . . | . . . | . . . |
| | 01 | 2.5 | 1.35 | 1.1 | . . . | . . . | . . . |
| | 10 | 3.3 | 1.5 | 1.0 | . . . | . . . | . . . |
| | 11 | 2.5 | 1.35 | 1.1 | . . . | . . . | . . . |

In Table 2, “Vₒᵤₜ₁” indicates a level of voltage applied to the NAND memory 61, “Vₒᵤₜ₂” indicates a level of voltage applied to the DRAM 62, and “Vₒᵤₜ₃” indicates a level of voltage applied to the controller 63. As shown in Table 2, the power source chip 10 may apply three more levels of voltage, that is, Vₒᵤₜ₄, Vₒᵤₜ₅, Vₒᵤₜ₆ in addition to the above-mentioned levels of voltage.

As shown in Table 2, the storage unit 32 stores the level combination of six voltages Vₒᵤₜ₁ Vₒᵤₜ₆ to be applied to the semiconductor package 65 with respect to each pattern of inputs to the power source chip 10.

In accordance with four patterns of inputs (0, 0), (0, 1), (1, 0), (1, 1), the setting unit 33 sets one combination of voltages Vₒᵤₜ₁-Vₒᵤₜ₆ to be applied to the semiconductor package 65. The output unit 34 supplies power to the NAND memory 61, the DRAM 62, and the controller 63 based on the level combination of voltage set by the setting unit 33.

Next, operation of the semiconductor system 1 according to this embodiment is explained.

The semiconductor package 65 may selectively adopt an interface from a plurality of interfaces, for example. That is, the semiconductor package 65 may adopt, for example, an interface of a SATA (Serial ATA) standard or an interface of a PCI Express (hereinafter referred to as PCIe) standard.

For example, when the semiconductor package 65 adopts the SATA standard interface, there may be a case where the NAND memory 61, the DRAM 62, and the controller 63 having a setting suitable for the interface are adopted. In this case, for example, one example of the combination of voltage levels required by the NAND memory 61, the DRAM 62, and the controller 63 (that is, the combination of voltage levels suitable for the semiconductor package 65 of the SATA standard) is (3.3 V, 1.5 V, 1.0 V).

On the other hand, for example, when the PCIe standard interface is adopted, there may be a case where the NAND memory 61, the DRAM 62, and the controller 63 having a setting suitable for the interface are adopted. In this case, for example, one example of the combination of voltage levels required by the NAND memory 61, the DRAM 62, and the controller 63 (that is, the combination of voltage levels suitable for the semiconductor package 65 of the PCIe standard) is (2.5 V, 1.35 V, 1.1 V).

It is desirable that the power source chip 10 is compatible with both the semiconductor package 65 of SATA standard and the semiconductor package 65 of PCIe standard. The power source chip 10 of this embodiment receives input from the semiconductor package 65 of SATA standard or from the semiconductor package 65 of PCIe standard, and supplies the combination of voltages required by the semiconductor package 65, for example, (3.3 V, 1.5 V, 1.0 V) or (2.5 V, 1.35 V, 1.1 V) to the semiconductor package 65.

To explain the configuration of the semiconductor system in more detail, FIG. 6 shows a first example of the semiconductor system 1. The first example corresponds to the semiconductor package 65 of the SATA standard. In the first measure, the first instruction terminal 21 of the semiconductor package 65 is electrically connected to the power source line so that a voltage of the first instruction terminal 21 is fixed to a High level (1). On the other hand, a second instruction terminal 22 is electrically connected to a ground so that a voltage of the second instruction terminal 22 is fixed to a Low level (0). Due to such a connection, an input (1, 0) is input to the power source chip 10 from the semiconductor package 65.

Upon receiving the input (1, 0), the power source chip 10 applies the combination of voltage levels (3.3 V, 1.5 V, 1.0 V) to the semiconductor package 65 as the combination of voltage levels (Vₒᵤₜ₁, Vₒᵤₜ₂, Vₒᵤₜ₃).

On the other hand, FIG. 8 shows a second example of the semiconductor system 1. The second example corresponds to the semiconductor package 65 of the PCIe standard. In the second example, the first instruction terminal 21 of the semiconductor package 65 is electrically connected to the ground so that a voltage of the first instruction terminal 21 is fixed to a Low level (0). On the other hand, the second instruction terminal 22 is electrically connected to the power source line so that a voltage of the second instruction terminal 22 is fixed to a High level (1). Due to such a connection, the input (0, 1) is input to the power source chip 10 from the semiconductor package 65.

Upon receiving the input (0, 1), the power source chip 10 applies the combination of voltage levels (2.5 V, 1.35 V, 1.1 V) to the semiconductor package 65 as the combination of voltage levels (Vₒᵤₜ₁, Vₒᵤₜ₂, Vₒᵤₜ₃). According to such a configuration, the power source chip 10 is compatible with both the semiconductor package 65 of the SATA standard and the semiconductor package 65 of the PCIe standard.

According to the above-mentioned configuration, it is possible to provide the power source chip 10 with a higher level of versatility, and the semiconductor system 1 which includes such a power source chip 10. That is, the power source chip 10 of this embodiment stores a plurality of level combinations of power to be supplied to the NAND memory 61, the DRAM 62, and the controller 63 in advance, selects one combination of powers from the plurality of combinations of powers in response to an input which the power source chip 10 receives, and supplies power to the NAND memory 61, the DRAM 62, and the controller 63 in accordance with the selected level combination of power.

According to such a configuration, the power source chip 10 may supply powers suitable for each combination of the NAND memory 61, the DRAM 62, and the controller 63 so that the versatility of the power source chip 10 may be enhanced.

Further, according to the above-mentioned configuration, level combinations of power to be supplied to the NAND memory 61, the DRAM 62, and the controller 63 may be collectively set based on an external input, and hence, it is unnecessary to adjust a power source for the NAND memory 61, the DRAM 62, and the controller 63 individually. Accordingly, it is possible to provide the power source chip 10 with a higher level of versatility.

In this embodiment, the semiconductor system 1 further includes a printed circuit board 72 in which a power source chip 10 is built, and a semiconductor package 65 which is mounted on the printed circuit board 72. The semiconductor package 65 includes the NAND memory 61, the DRAM 62, and the controller 63. According to such a configuration, for example, the same power source chip 10 may be used for different semiconductor packages 65.

In this embodiment, the semiconductor package 65 transmits an input which is used to set the level combination of power the NAND memory 61, the DRAM 62, and the controller 63 to the power source chip 10. Due to such a configuration, based on the input from the semiconductor package 65, the level combination of power to be supplied to the NAND memory 61, the DRAM 62, and the controller 63 respectively is collectively decided. Accordingly, power sources suitable for the NAND memory 61, the DRAM 62, and the controller 63 individually may be surely provided.

That is, it becomes unnecessary to adjust a level of power for the NAND memory 61, the DRAM 62, and the controller 63 respectively. Accordingly, it is possible to avoid a situation where excessively large power is supplied to one or more of the NAND memory 61, the DRAM 62, and the controller 63 caused by mistakenly adjusting a level of power for the NAND memory 61, the DRAM 62, and the controller 63 respectively.

The power source chip 10 is built in the printed circuit board 72. In such a case, when the chip on the surface of the printed circuit board is replaced with another chip that requires different power, it was necessary to redesign a printed circuit board.

According to the configuration of this embodiment, however, even when the semiconductor package 65 mounted on the surface of the printed circuit board is changed, the same power source chip 10 may be used. That is, the power source chip 10 may be used in common, and hence, it is unnecessary to redesign the printed circuit board 72 in accordance with the new semiconductor package 65 mounted on the surface of the printed circuit board, so that a manufacturing cost may be lowered. Further, when the power source chip 10 is built in the printed circuit board 72, a size of the printed circuit board 72 may be made small.

For a comparison purpose, a case is considered where setting of powers to be supplied to the NAND memory 61, the DRAM 62, and the controller 63 is controlled by the controller 63. In this case, to perform the above-mentioned setting, it is necessary that the controller 63 is operated. Accordingly, a time and power for operating the controller 63 are necessary to perform the above-mentioned input.

To the contrary, in this embodiment, the input unit 31 of the power source chip 10 includes input terminals 23, 24. The above-mentioned input which is used to set levels of power to be supplied to the NAND memory 61, the DRAM 62, and the controller 63 is performed by fixing voltages applied to the input terminals 23, 24 at a level lower than a predetermined voltage or at a level higher than the predetermined voltage. Due to such a configuration, even when the semiconductor package 65 is not operated (that is, even when the controller 63 is not operated), proper input may be carried out to the power source chip 10. Accordingly, a rise time of the semiconductor system 1 may be shortened and standby power may be reduced.

### Fourth Embodiment

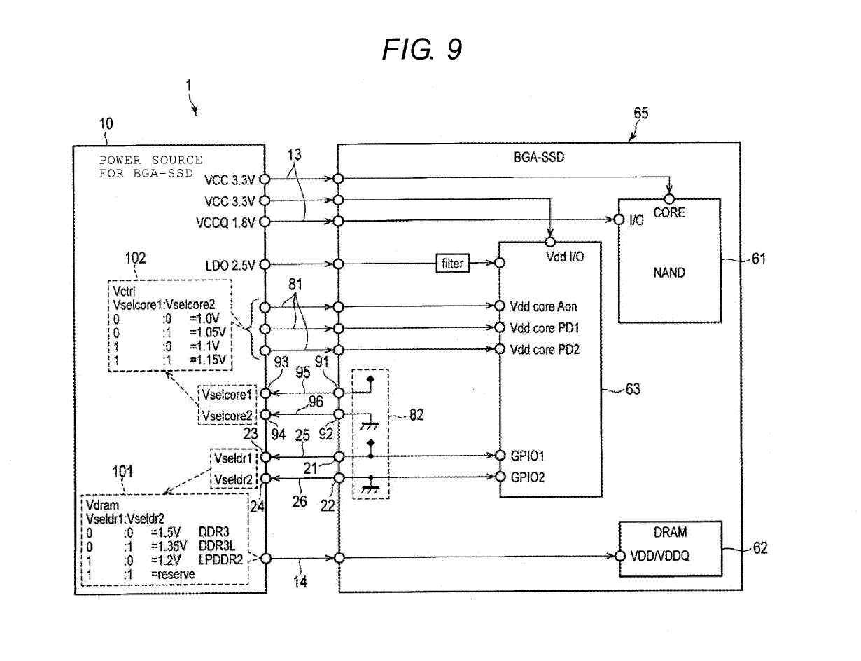

Next, a semiconductor system 1 according to a fourth embodiment is explained by reference to FIG. 9. An element that is equal to or similar to the corresponding element of the first to third embodiments is shown with a same symbol, and explanation of these elements is omitted. Elements other than the elements explained below are equal to the corresponding elements of the third embodiment.

FIG. 9 shows the semiconductor system 1 according to the fourth embodiment. The semiconductor system 1 includes a power source chip 10, a NAND memory 61, a DRAM 62, and a controller 63. The power source chip 10 supplies power to the NAND memory 61, the DRAM 62, and the controller 63.

As shown in FIG. 9, a reference unit 82 of the semiconductor package 65 is electrically connected to a first instruction terminal 21, a second instruction terminal 22, a third instruction terminal 91 (third terminal, third set terminal, third output terminal), and a fourth instruction terminal 92 (fourth terminal, fourth set terminal, fourth output terminal). Based on the configuration of the reference unit 82, for example, the semiconductor package 65 may set respective voltages applied to the first to fourth instruction terminals 21, 22, 91, and 92. An input unit 31 of the power source chip 10 includes: a first input terminal 23; a second input terminal 24; a third input terminal 93 (third terminal); and a fourth input terminal 94 (fourth terminal).

A first input line 25 is provided between the first instruction terminal 21 of the semiconductor package 65 and the first input terminal 23 of the power source chip 10, and a first input is transmitted to the first input terminal 23 of the power source chip 10 through the first input line 25. A second input line 26 is provided between the second instruction terminal 22 of the semiconductor package 65 and the second input terminal 24 of the power source chip 10, and a second input is transmitted to the second input terminal 24 of the power source chip 10 through the second input line 26. A third input line 95 is provided between the third instruction terminal 91 of the semiconductor package 65 and the third input terminal 93 of the power source chip 10, and a third input is transmitted to the third input terminal 93 of the power source chip 10 through the third input line 95. A fourth input line 96 is provided between the fourth instruction terminal 92 of the semiconductor package 65 and the fourth input terminal 94 of the power source chip 10, and a fourth input is transmitted to the fourth input terminal 94 of the power source chip 10 through the fourth input line 96.

In this embodiment, the input of the first to fourth inputs is performed by fixing respective voltages applied to the first to fourth input terminals 23, 24, 93, and 94 of the power source chip 10 to a level lower than a desired voltage (predetermined voltage) or to a level higher than the desired voltage (predetermined voltage), for example.

To be more specific, the first to fourth instruction terminals 21, 22, 91, and 92 of the semiconductor package 65 are electrically connected to a ground or to a power source line of the semiconductor package 65 or a printed circuit board 72 respectively, for example. Due to such a connection, the semiconductor package 65 may perform plural kinds of inputs to the power source chip 10 based on the level combinations of voltage applied to the first to fourth input terminals 23, 24, 93, and 94.

In this embodiment, the power source chip 10 includes a first storage unit 101 and a second storage unit 102. A relationship between a level of voltage applied to the DRAM62 with respect to each of four kinds of inputs (0, 0), (0, 1), (1, 0), and (1, 1) to the first and second input terminals 23, 24, is stored in the first storage unit 101 in advance. A relationship between a level of voltage applied to the controller 63 with respect to each of four kinds of inputs (0, 0), (0, 1), (1, 0), (1, 1) to the third and fourth input terminals 93, 94 is stored in the second storage unit 102 in advance.

The setting unit 33 sets power (voltage) to be supplied to the DRAM 62 in accordance with one of the four kinds of inputs (0, 0), (0, 1), (1, 0), (1, 1) to the first and second input terminals 23, 24. The setting unit 33 also selects power (voltage) to be supplied to the controller 63 in accordance with one of the four kinds of inputs (0, 0), (0, 1), (1, 0), (1, 1) to the third and fourth input terminals 93, 94. The output unit 34 supplies powers to the NAND memory 61, the DRAM 62, and the controller 63 based on the level combination of power which are set by the setting unit 33.

According to the above-mentioned configuration, it is possible to provide the power source chip 10 with a higher level of versatility, and the semiconductor system 1 which includes such a power source chip 10. That is, according to the above-mentioned configuration, the power source chip 10 may supply powers suitable for each combination of the NAND memory 61, the DRAM 62, and the controller 63 so that versatility of the power source chip 10 may be enhanced.

Further, according to the above-mentioned configuration, the level combination of power to be supplied to the NAND memory 61, the DRAM 62, and the controller 63 may be collectively set based on external inputs, and hence, it is unnecessary to adjust a level of power to be supplied to the NAND memory 61, the DRAM 62, and the controller 63 individually. According to such a configuration, it is possible to provide the power source chip 10 with a higher level of versatility.

In this embodiment, the semiconductor package 65 transmits inputs, which are used to set the level combination of power to the NAND memory 61, the DRAM 62, and the controller 63, to the power source chip 10. According to such a configuration, the level combination of power to be supplied to the NAND memory 61, the DRAM 62, and the controller 63 is collectively decided based on the inputs from the semiconductor package 65. Accordingly, the power source chip 10 may surely supply powers suitable for the NAND memory 61, the DRAM 62, and the controller 63 individually.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor system comprising:
a semiconductor package having first and second semiconductor chips and a controller configured to control the first and second semiconductor chips; and
a power source chip that is connected to a control line of the semiconductor package, and is configured to supply, to the first and second semiconductor chips and the controller, power having a level that correspond to a voltage level of the control line.

2. The semiconductor system according to claim 1, wherein the first semiconductor chip is a NAND memory, and the second semiconductor chip is a DRAM.

3. The semiconductor system according to claim 1, wherein the power is supplied at different voltage levels depending on the voltage level of the control line.

4. The semiconductor system according to claim 3, wherein
the voltage level of power supplied to the first semiconductor chip is different from the voltage level of power supplied to the second semiconductor chip.

5. The semiconductor system according to claim 3, wherein
the voltage level of power supplied to the first semiconductor chip is different from the voltage level of power supplied to the controller.

6. The semiconductor system according to claim 1, wherein the voltage level of the control line is at a first level that is higher than a predetermined level or a second level that is lower than the predetermined level.

7. The semiconductor system according to claim 1, wherein
the power source chip includes a first terminal connected to one of the control line and ground and a second terminal connected the other of the control line and ground, and
the power source chip is configured to supply, to the first and second semiconductor chips and the controller, the power at different voltage or current levels depending on voltage levels of the first and second terminals, respectively.

8. The semiconductor system according to claim 7, wherein
the power source chip includes a storage unit storing a relationship among the voltage levels of the first and second terminals and the voltage or current levels of the power to be supplied to the first and second semiconductor chips and the controller.

9. A power source chip, comprising:
an input unit configured to be connected to a control line of a first semiconductor chip; and
an output unit configured to output power at different voltage or current levels to plural terminals according to a voltage level of the input unit.

10. The power source chip according to claim 9, further comprising:
a storage unit configured to store a relationship among a voltage level of the input unit and the levels of power to be output; and
a setting unit configured to set levels of power to be output based on the voltage level of the input unit and the stored relationship, wherein
the output unit is configured to output the power of the set levels.

11. The power source chip according to claim 10, wherein
the input unit includes a first terminal configured to be connected to one of the control line and ground, and a second terminal configured to be connected to the other of the control line and ground,
the stored relationship is a relationship among voltage levels of the first and second terminals and the levels of power to be output.

12. The power source chip according to claim 11, wherein the output unit is configured to output the power to a second semiconductor chip that is different from the first semiconductor chip.

13. The power source chip according to claim 9, wherein the power output by the output unit to the plural terminals has different power levels.

14. The power source chip according to claim 9, wherein the output unit is configured to output the power to a second semiconductor chip that is different from the first semiconductor chip.

15. The power source chip according to claim 9, wherein the voltage level of the control line is at a first level that is higher than a predetermined level or a second level that is lower than the predetermined level.

16. The power source chip according to claim 9, wherein
the input unit includes a first terminal configured to be connected to one of the control line and ground, and a second terminal configured to be connected to the other of the control line and ground,
the output unit is configured to output the power having different voltage or current levels depending on a voltage level of the first terminal and a voltage level of the second terminal, respectively.

17. A method for operating a power source chip of a semiconductor system including a semiconductor package having first and second chips and a controller configured to control the first and second chips, said method comprising:
detecting a voltage level of a control line of the semiconductor package;
setting voltage levels or current levels of power to be output based on the voltage level of the control line and a relationship among a voltage level of the terminal and levels of power to be output; and
outputting the power having the set voltage or current levels to the first and second chips and the controller.

18. The method according to claim 17, wherein the first chip is a NAND memory, and the second chip is a DRAM.

19. The method according to claim 17, wherein the power is output at a voltage level that has been set.

20. The method according to claim 17, wherein the power is output at a current level that has been set.
